(19) United States
(12) Patent Application Publication
(10) Pub. No.: US 2013/0087197 A1
(43) Pub. Date: Apr. 11, 2013

(54) CONCENTRATED PHOTOVOLTAIC SOLAR CELL PACKAGING USING LAMINATED SUBSTRATES AND AN OPEN WINDOW OVERMOLDING PROCESS

(71) Applicant: BrightLeaf Technologies, Inc., Montrose, CO (US)

(72) Inventor: Hing Chan, San Jose, CA (US)

(73) Assignee: BrightLeaf Technologies, Inc., Montrose, CO (US)

(21) Appl. No.: 13/646,370

(22) Filed: Oct. 5, 2012

Related U.S. Application Data
(60) Provisional application No. 61/543,580, filed on Oct. 5, 2011.

(51) Int. Cl. H01L 31/0203; H01L 31/18; H01R 43/00

(52) U.S. Cl. 136/259; 29/748; 438/64; 156/500; 257/E31.117

(57) ABSTRACT

A method of concentrated photovoltaic (CPV) packaging of a semiconductor solar cell for converting solar energy into electricity. The method includes affixing a photovoltaic device to a laminated substrate structure that is obtained by an additive or subtractive lamination process, attaching a photovoltaic device to a mounting paddle of the laminated substrate structure, connecting wire bonding of the photovoltaic device to leads of the laminated substrate structure, and applying overmold material to affix the photovoltaic device to the mounting paddle. During the application of the overmold material, a portion of the photovoltaic device is exposed to allow for the collection of the solar energy.

### CROSS REFERENCE TO RELATED APPLICATIONS

This application claims the benefit of the filing date of U.S. Provisional Patent Application No. 61/543,580, attorney docket number 002107,000020, filed on Oct. 5, 2011, the disclosure of which is incorporated by reference herein in its entirety.

### FIELD OF THE INVENTION

The present disclosure relates in general to concentrated photovoltaic (CPV) solar cell packaging through an open window molding process. More specifically, the present disclosure includes solar cell packaging that involves affixing a photovoltaic device to a laminated substrate structure that is obtained by an additive or subtractive lamination process. The laminated substrate structure has an electrically insulative layer to isolate both the cathode and anode from ground (i.e., high potential requirement) for the CPV solar cell package.

### DESCRIPTION OF PRIOR ART

Semiconductor electronic components may be embedded in a semiconductor package having, for example, molded plastic or ceramic casing. The semiconductor package typically includes leads or contacts for connecting to devices. Specifically, solar cell packages may include embedded photovoltaic cells that convert electromagnetic energy from a light source to electricity. Examples of prior art CPV solar cell packages are shown in FIGS. 1-2.

In FIG. 1, a leadframe based CPV solar cell package 100 is shown having a thermally sprayed coated ceramic layer 102. The ceramic layer 102 is thermally sprayed onto a leadframe having a mounting paddle 104 and leadframe leads 105. A semiconductor die 106 is attached to the mounting paddle 104 and wire bonded 108 to the leadframe leads 105. The entire package 100 is then encapsulated in an overmold material 110. Typically, the leadframe based solar cell package 100 fails high potential testing because the ceramic layer 102 does not sufficiently insulate the leadframe. A secondary cause of insufficient insulation may be exposed edges (not shown) that are created when the support structure of the leadframe is sheared off to isolate the cathode and anode after singulation. In some cases, the high potential requirements may be satisfied in a leadframe based solar cell package 100 by fusing an additional layer of ceramic (not shown), which adds cost and complexity to the package 100.

In FIG. 2, a direct bonded copper (DBC) substrate based CPV solar cell package 200 is shown having a sandwiched substrate. The mounting paddle 204 and bonding pad 205 are etched structures affixed to a DBC substrate 202 having an alumina layer. A semiconductor die 206 is attached to the mounting paddle 204 and wire bonded 208 to the bonding pad 205. The entire package 200 is then encapsulated in an overmold material 210. Substrate based solar cell packages 200 typically satisfy the high potential requirements; however, DBC substrates (1) have a relatively high cost and (2) are available in limited form factors (e.g., 5″×7″).

### SUMMARY OF THE INVENTION

Disclosed herein are example embodiments of a method of packaging a semiconductor solar cell that converts solar energy into electricity. In one embodiment, the method includes affixing a photovoltaic device to a laminated substrate structure that is obtained by an additive or subtractive lamination process, attaching a photovoltaic device to a mounting paddle of the laminated substrate structure, connecting wire bonding of the photovoltaic device to leads of the laminated substrate structure, and applying overmold material to affix the photovoltaic device to the mounting paddle. During the application of the overmold material, a portion of the photovoltaic device is exposed to allow for the collection of the solar energy.

### BRIEF DESCRIPTION OF THE DRAWINGS

Some of the features and benefits of the present invention having been stated, others will become apparent as the description proceeds when taken in conjunction with the accompanying drawings, in which:

FIGS. 1-2 are side perspective views of prior art solar cell packages.

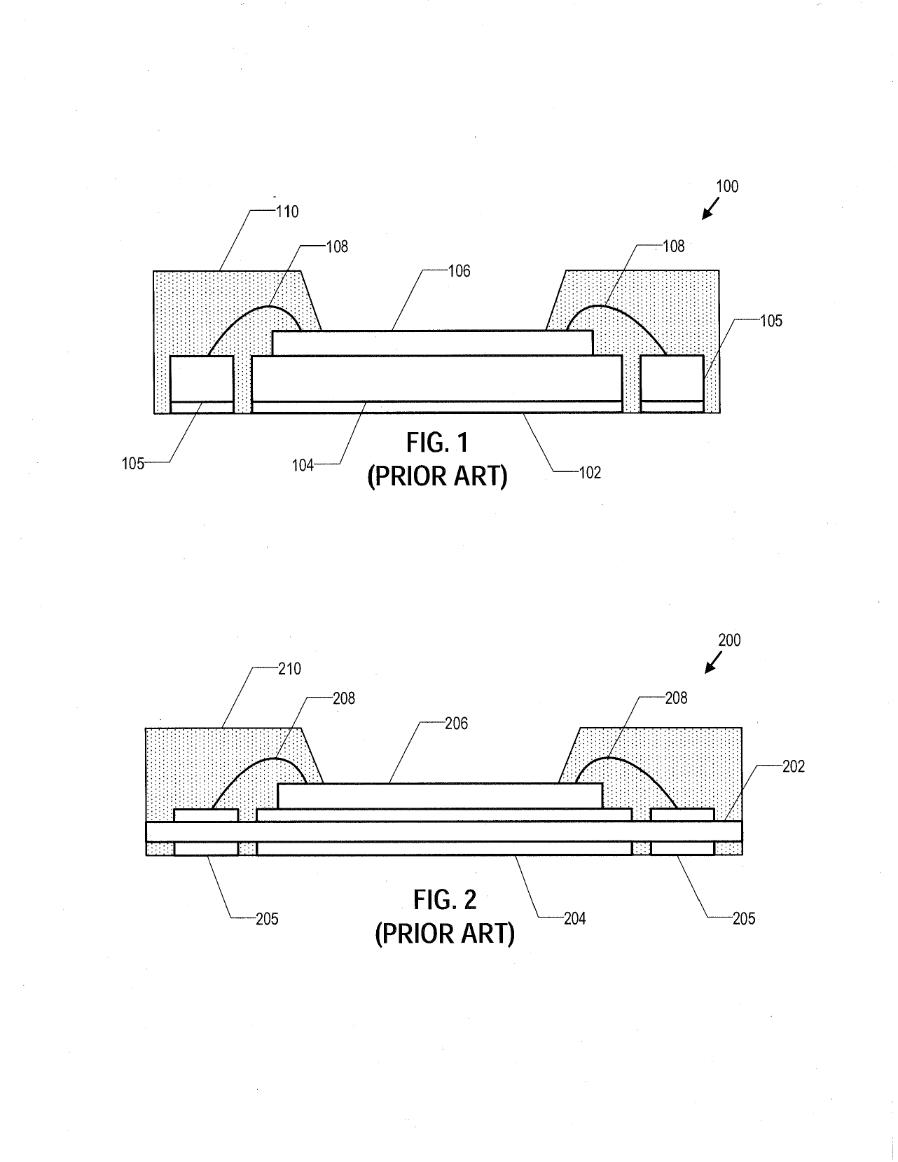

FIG. 3 is a side view of an example of a solar cell package in accordance with the present disclosure.

FIG. 4 is a workflow example for an additive process of preparing solar cell packages in accordance with the present disclosure.

FIGS. 5A-5D are examples of a solar cell package at various stages of completion in accordance with the present disclosure.

FIGS. 6A and 6B are side views of examples of solar cell packages in accordance with the present disclosure.

FIG. 7 is a workflow example for a subtractive process of preparing solar cell packages in accordance with the present disclosure.

FIGS. 8A-8D are examples of a solar cell package at various stages of completion in accordance with the present disclosure.

FIGS. 9A-9B show an example system for performing an additive process of preparing solar cell packages in accordance with the present disclosure.

It will be understood the improvement described herein is not limited to the embodiments provided. On the contrary, the present disclosure is intended to cover all alternatives, modifications, and equivalents, as may be included within the spirit and scope of the improvement as defined by the appended claims.

### DETAILED DESCRIPTION OF THE INVENTION

The present invention will now be described more fully hereinafter with reference to the accompanying drawings in which embodiments of the invention are shown. This invention may, however, be embodied in many different forms and should not be construed as limited to the illustrated embodiments set forth herein; rather, these embodiments are provided so that this disclosure will be thorough and complete, and will fully convey the scope of the invention to those skilled in the art. Like numbers refer to like elements throughout. For the convenience in referring to the accompanying figures, directional terms are used for reference and illustration only.

It is to be understood that the invention is not limited to the exact details of construction, operation, exact materials, or embodiments shown and described, as modifications and equivalents will be apparent to one skilled in the art. In the drawings and specification, there have been disclosed illustrative embodiments of the invention and, although specific terms are employed, they are used in a generic and descriptive sense only and not for the purpose of limitation.

Described herein are example systems and methods for packaging solar cells. In one exemplary embodiment, a method includes laminating an electrically insulative but thermally conductive film to a leadframe in order to improve insulation and satisfy high potential requirements. Additional embodiments described herein include preparing a mounting paddle and leads of the laminated structure (e.g., flexible substrate) to hold a photovoltaic device. One example embodiment includes an overmold material that affixes the photovoltaic device to the laminated structure.

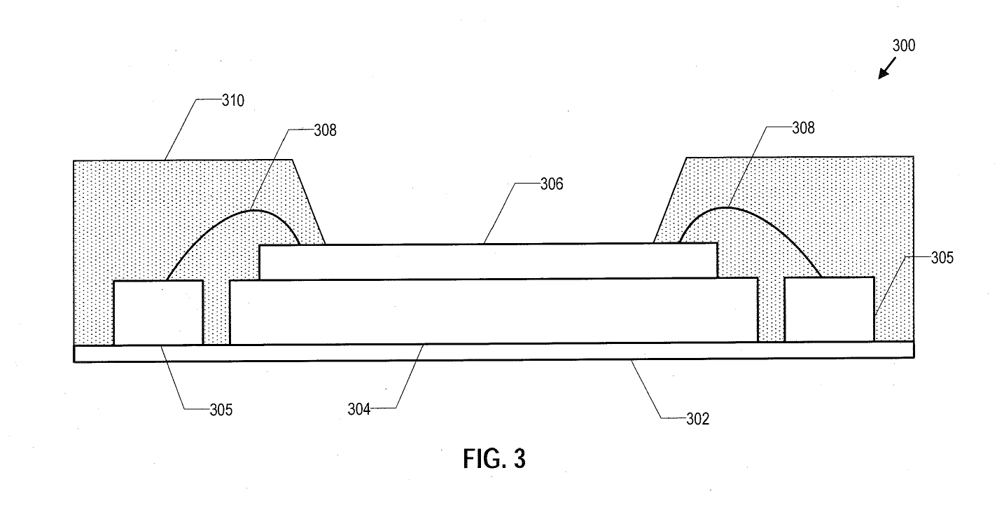

An example of a solar cell package 300 described herein is shown in a side partial sectional view in FIG. 3. The solar cell package 300 of FIG. 3 includes an electrically insulative film layer 302 attached to a bottom portion of metal conductors such as a leadframe having a mounting paddle 304 and leads 305. The insulative film layer 302 may be an adhesive layer that is laminated to the mounting paddle 304 and leads 305 by applying increasing pressure to a leadframe positioned on the adhesive layer. In an exemplary embodiment, the leadframe may be positioned on the insulative film layer 302 such that the mounting paddle 304 is separate from the leads 305. In other embodiments, the laminated structure may be formed by laminating sheets of material. For example, the laminated structure may include a copper sheet, a polyimide sheet (i.e., insulative film layer 302), and a supporting copper sheet (not shown). In this example, copper may be etched away from the copper sheet to form the mounting paddle 304 and the leads 305. As shown, the laminated structure has two leads 305; however, any number of leads 305 may be included in the solar cell package 300 for connecting to a photovoltaic device 306.

in an exemplary embodiment, the photovoltaic device 306 is electrically and mechanically attached to the mounting paddle 304 of the laminated structure through a die attachment process soldering, epoxy die attach, etc.), and wire bonding 308 of the photovoltaic device 306 is connected to the leads 305 of the laminated structure. The photovoltaic device 306 may be configured to collect solar energy for converting to electricity, which is communicated through the wire bonding 308 to the leads 305. In an exemplary embodiment, the photovoltaic device 306 is affixed to the laminated structure by an overmold material 310. For example, the overmold material 310 may include plastic molding compounds such as epoxy resins, acrylics, silicones, etc.

Examples of an insulative film layer 302 include, but are not limited to, thermally conductive silicone, polyimide or epoxy film with improved thermal conductivity through the addition of ceramic fillers such as alumina, aluminum nitride, etc. As discussed above, the insulative film layer 302 increases high potential (hipot) values of the package by improving insulation. Hipot testing of the solar cell package 300 can verify that the electrical insulation 302 is sufficient to prevent electrical leakage. In this case, high hipot values indicate that excessive leakage through the insulative film layer 302 is not occurring. In addition, the insulative film layer 302 may be thermally conductive in order to prevent the photovoltaic device 306 from becoming overheated.

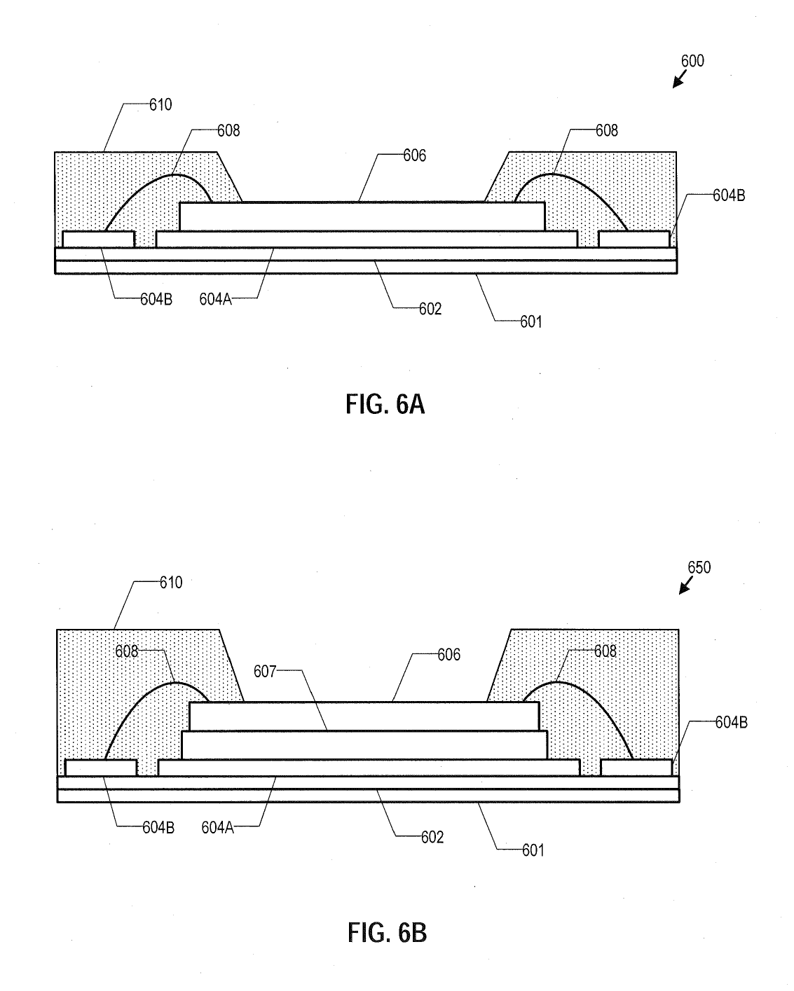

In the case of flex circuitry type polyimide film, the insulative film layer 302 may be plated or physically bonded to a metallic material (e.g., a copper alloy including at least one of nickel, manganese, cobalt, phosphorus, zirconium, silicon, silver, and iron) in order to enhance the electrical or thermal properties of the insulative film layer 302. In an exemplary embodiment, the flex circuitry type polyimide film exhibits the aforementioned desired thermal and electrical properties when minimal thickness (e.g., 17 microns) of the film is achieved. In one embodiment, an additional supporting layer (e.g., a copper sheet) (not shown) may be laminated to the bottom of the insulative film layer 302 to provide support for the solar cell package 300 (e.g., as discussed below with respect to FIGS. 6A and 6B).

In some embodiments, the solar cell package 300 further includes a metal slug (not shown) between the photovoltaic device 306 and the mounting paddle 304 of the metal layer. The metal slug may be a thermally and electrically conductive material, such as copper, that increases the efficiency of heat transfer through the flex circuitry type polyimide film layer 302. In an exemplary embodiment, the metal slug is soldered to the mounting paddle 304 to improve thermal conductivity.

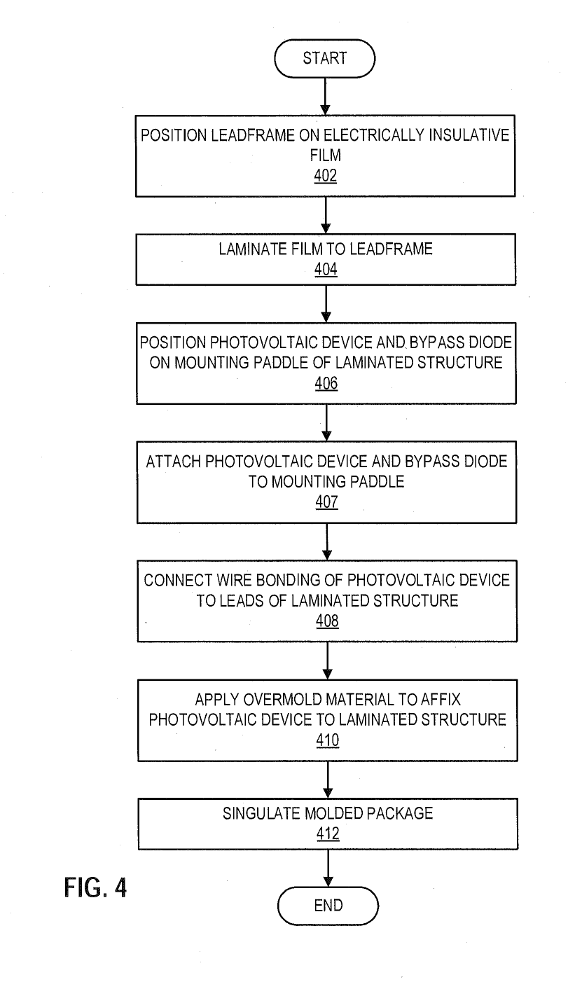

FIG. 4 shows a workflow example for an additive process of preparing solar cell packages in accordance with the present disclosure. As is the case with the other processes described herein, various embodiments may not include all of the steps described below, may include additional steps, and may sequence the steps differently. Accordingly, the specific arrangement of steps shown in FIG. 4 should not be construed as limiting the scope of the invention.

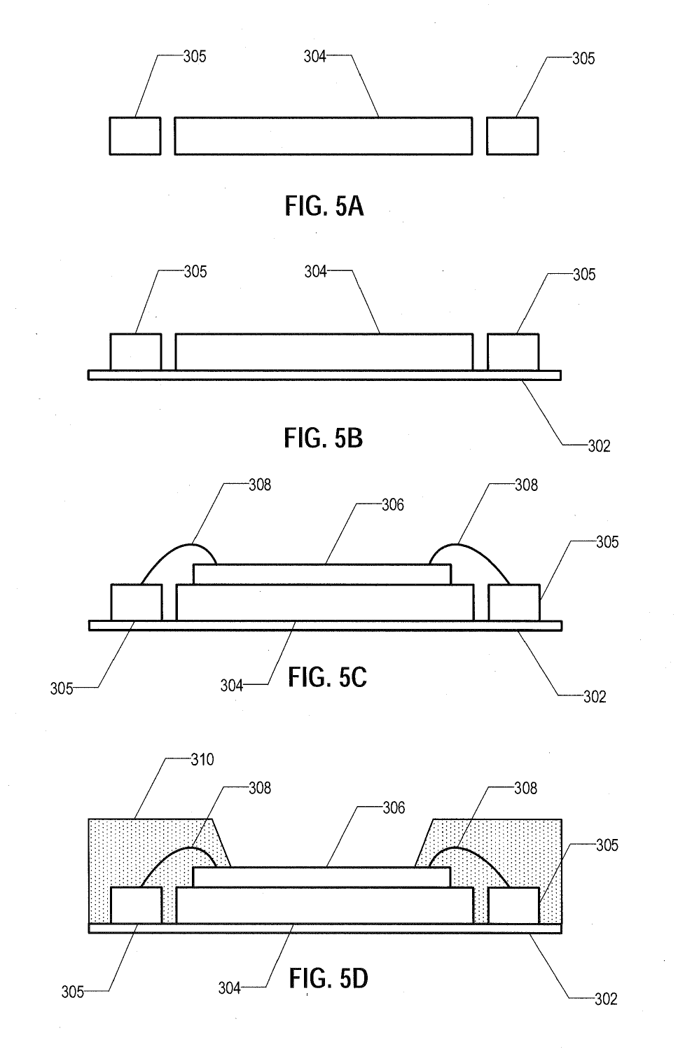

In step 402, a leadframe is positioned on electrically insulative film 302. Initially, as shown in FIG. 5A, a leadframe having a mounting paddle 304 and leads 305 may be isolated. FIG. 5B shows the mounting paddle 304 and leads 305 positioned on the electrically insulative film 302.

In step 404, the electrically insulative film 302 is laminated to the leadframe. For example, pressure may be applied to the mounting paddle 304 and leads 305 to bond the leadframe to an adhesive layer or directly to the electrically insulative film 302 as shown in FIG. 5B. In this example, the adhesive layer may include an epoxy resin for bonding to the leadframe. As discussed above, the electrically insulative film 302 may exhibit electrically insulative and thermally conductive properties in order to maximize hipot values. As shown in FIG. 5B, the electrically insulative film 302 is continuous thereby preventing edge exposure of the leadframe.

In step 406, a photovoltaic device 306 and bypass diode (not shown) are positioned on the mounting paddle 304 of the laminated structure as, for example, shown in FIG. 5C. In step 407, the photovoltaic device 306 and bypass diode (not shown) are attached (e.g., soldered with lead free solders, epoxy die attach, etc.) to the mounting paddle 304. Once attached, the photovoltaic device 306 may conduct converted electricity to the mounting paddle 304. In step 408, wire bonding 308 is applied to operatively connects the photovoltaic device 306 to the leads 305 as, for example, shown in FIG. 5C.

In step 410, an overmold material 310 is applied to affix the photovoltaic device 306 to the mounting paddle 304. As shown in FIG. 5D, an opening is positioned in the overmold material 310 to expose a portion of the photovoltaic device 306 thereby allowing the photovoltaic device 306 to capture solar energy. In some embodiments, additional openings may be positioned in the overmold material 310 to expose output connections for the mounting paddle 304 and leads 305 (e.g., an output cathode connection, an output anode connection, etc.) thereby allowing converted electricity to be obtained from the photovoltaic device 306.

In step 412, the molded solar cell package is singulated. Specifically, the molded solar cell package may be singulated by cutting (e.g., by focused beam or saw blade) the package from an integrated circuit sheet.

An example of a solar cell package 600 described herein is shown in a side partial sectional view in FIG. 6A. The solar cell package 600 of FIG. 6A includes a laminated sandwich substrate having a metal layer 604A and 604B (e.g., a copper layer), a flex circuitry type polyimide film layer 602, and a supporting metal layer 601 (e.g., a supporting copper layer). As shown in FIG. 6A, the flex circuitry type polyimide film layer 602 is laminated between the metal layer 604A and 604B and the supporting metal layer 601. In this example, material is etched away from the metal layer to form a mounting paddle 604A and leads 604B. In an exemplary embodiment, the material is etched away from the metal layer such that the mounting paddle 604A is separate from the leads 604B. As shown, the laminated sandwich substrate has two leads 604B; however, any number of leads 604B may be formed when material is etched from the metal layer.

In an exemplary embodiment, the photovoltaic device 606 is attached to the mounting paddle 604A of the laminated sandwich substrate, and wire bonding 608 of the photovoltaic device 606 is connected to the leads 604B of the laminated sandwich substrate. The photovoltaic device 606 may be configured to collect solar energy for converting to electricity, which is communicated through the wire bonding 608 to the leads 604B. In an exemplary embodiment, the photovoltaic device 606 is affixed to the laminated sandwich substrate by an overmold material 610. For example, the overmold material 610 may include plastic molding compounds such as epoxy resins, acrylics, silicones, etc.

The flex circuitry type polyimide film layer 602 increases high potential (“hipot”) values of the package by improving insulation. In some embodiments, the flex circuitry type polyimide film layer 602 may be thermally conductive in order to prevent the photovoltaic device from becoming overheated. In addition, the supporting metal layer 601 may enhance the electrical or thermal properties of the flex circuitry type polyimide film layer 602. In an exemplary embodiment, the flex circuitry type polyimide film 602 exhibits the aforementioned desired thermal and electrical properties when minimal thickness (e.g., 17 microns) of the film is achieved.

An example of a solar cell package 650 described herein is shown in a side partial sectional view in FIG. 6B. The solar cell package 650 of FIG. 6B is substantially similar to the solar cell package 600 discussed with respect to FIG. 6A except for the differences discussed below. As shown in FIG. 6B, the solar cell package 650 further includes a metal slug 607 between the photovoltaic device 606 and the mounting paddle 604A of the metal layer. The metal slug 607 may be a thermally and electrically conductive material, such as copper, that increases the efficiency of heat transfer through the flex circuitry type polyimide film layer 602. In an exemplary embodiment, the metal slug 607 is soldered to the mounting paddle 604A to improve thermal conductivity.

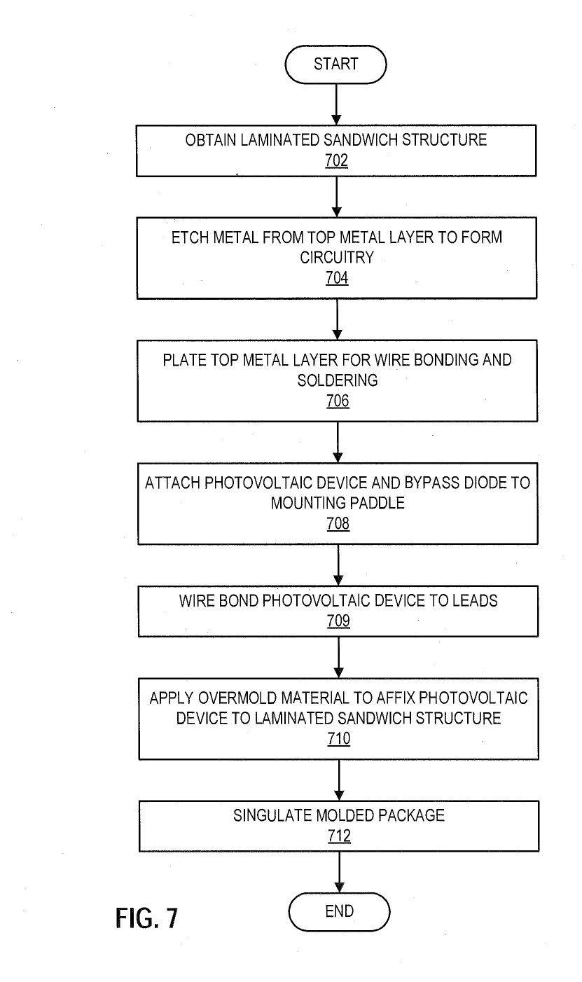

FIG. 7 shows a workflow example for a subtractive process of preparing solar cell packages in accordance with the present disclosure. As is the case with the other processes described herein, various embodiments may not include all of the steps described below, may include additional steps, and may sequence the steps differently. Accordingly, the specific arrangement of steps shown in FIG. 7 should not be construed as limiting the scope of the invention.

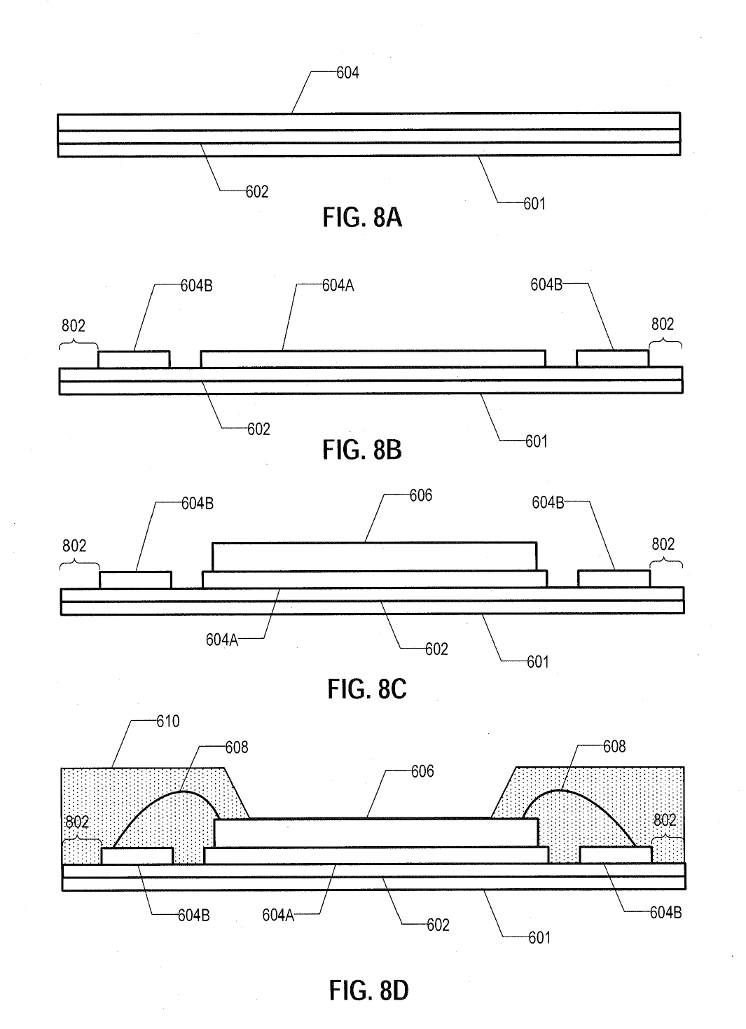

In step 702, a laminated sandwich substrate is obtained. Initially, as shown in FIG. 8A, the laminated sandwich substrate has a copper sheet 604, a polyimide sheet 602, and a supporting copper sheet 601. In some embodiments, the supporting copper sheet 601 may be used to attach the completed solar cell package as shown in FIG. 8D in subsequent assemblies.

In step 704, copper is etched away from the copper sheet 604 of the laminated sandwich substrate to form the mounting paddle 604A and leads 604B as shown in FIG. 8B. As shown in FIG. 8B, a copper-free border 802 may also be etched from around the edges of the metal sheet. In this case, the copper-free border 802 surrounds the metal layer 604A and 604B and exposes the polyimide sheet 602. The polyimide sheet 602 exposed by the copper-free border 802 may increase hipot values (i.e., provide hipot resistance). Specifically, the copper-free border 802 increases hipot values by preventing edge exposure of the copper sheet 604A and 604B after singulation is performed as discussed below in step 712.

In step 706, the mounting paddle 604A and leads 604B of the copper sheet are appropriately plated with metals for later die attachment processes (e.g., step 708 discussed below) and interconnecting processes such as wire bonding (e.g., step 709 discussed below).

In step 708, a photovoltaic device 606 and bypass diode (not shown) are attached (e.g., soldered with lead free solders, epoxy die attach, etc.) to the mounting paddle 604A of the laminated sandwich substrate as, for example, shown in FIG. 8C. Once attached, the photovoltaic device 606 may conduct converted electricity to the mounting paddle 604A. In step 709, wire bonding 608 is applied to operatively connect the photovoltaic device 606 to the leads 604B as, for example, shown in FIG. 8D.

In step 710, an overmold material 610 is applied to affix the photovoltaic device 606 to the mounting paddle 604A. As shown in FIG. 8D, an opening is positioned in the overmold material 610 to expose a portion of the photovoltaic device 606 thereby allowing the photovoltaic device 606 to capture solar energy. In some embodiments, additional openings may be positioned in the overmold material 610 to expose output connections for the mounting paddle 604A and leads 604B (e.g., an output cathode connection, an output anode connection, etc.) thereby allowing converted electricity to be obtained from the photovoltaic device 606.

In step 712, the molded solar cell package is singulated. Specifically, the molded solar cell package may be singulated by cutting (e.g., by focused beam or saw blade) the package from the laminated sandwich substrate.

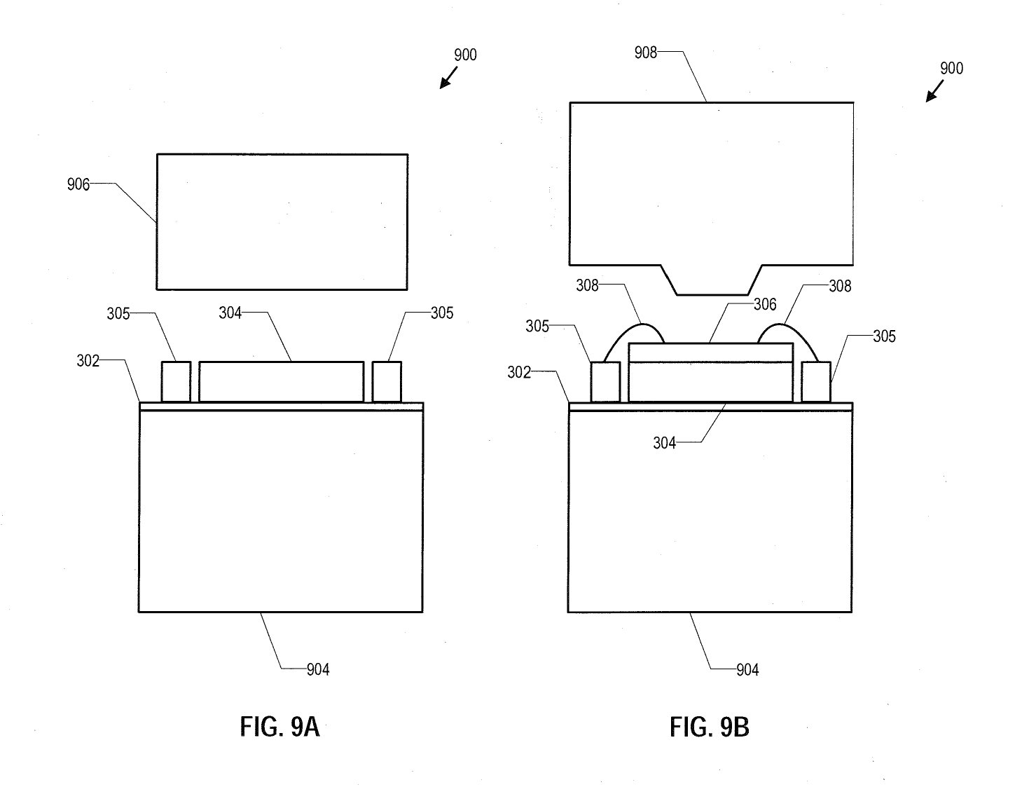

An example of a solar packaging system 900 is shown schematically in FIGS. 9A and 9B. In this example the solar packaging system 900 includes a bottom mold 904, a lamination device 906 in FIG. 9A, and a top mold 908 in FIG. 9B. Electrically insulative film 302 may be positioned on the bottom mold 904 as shown in FIG. 9A using a film device (not shown) such as a film conveyer. After the electrically insulative film 302 is properly positioned over the bottom mold 904, a leadframe having a mounting paddle 304 and leads 305 may be positioned on the electrically insulative film 302 such that the mounting paddle 304 is separate from the leads 305. Prior to positioning the leadframe, the electrically insulative film 302 may be drawn down into the bottom mold 904 using a drawdown device such as a vacuum. In this case, the electrically insulative film 302 forms to the surface of the bottom mold 904 to accommodate various shaped leadframes.

To laminate the electrically insulative film 302 to the mounting paddle 304 and the leads 305, the lamination device 906 of FIG. 9A may descend to apply pressure to the mounting paddle 304 and the leads 305. Once lamination is complete, a photovoltaic device 306 may be positioned on the mounting paddle 304 with wire bonding 308 connected to the leads 305 as shown in FIG. 9B by a bonding component (not shown) that is affixed to the lamination device 906 for performing, for example, thermosonic bonding. To affix the photovoltaic device, the lamination device 906 of FIG. 9A may be removed to allow the top mold 908 of FIG. 9B to descend and apply the overmold material (not shown). In some embodiments, a teflon film is applied to the top mold 908 of FIG. 9B to protect the photovoltaic device 306 during the application of the overmold material. As shown in FIG. 9B, the top mold 908 includes a protrusion from the bottom portion of the top mold 908 that may be used to position an opening on the photovoltaic device 306 as the overmold material is applied. After encapsulation, the solar cell package may then be removed from the bottom mold 904 using a removal device (not shown) such as a robotic arm.

Though only a single package is shown in FIGS. 9A and 9B, the solar packaging system 900 may be configured to prepare any number of packages supported by a single sheet of electrically insulative film 302. In this case, each of the packages may be cut from the single sheet of electrically insulative film 302 during a singulation process performed by a singulation device (not shown) such as a focused beam or saw blade.

The present invention described herein, therefore, is well adapted to carry out the objects and attain the ends and advantages mentioned, as well as others inherent therein. While a presently preferred embodiment of the invention has been given for purposes of disclosure, numerous changes exist in the details of procedures for accomplishing the desired results. These and other similar modifications will readily suggest themselves to those skilled in the art, and are intended to be encompassed within the spirit of the present invention disclosed herein and the scope of the appended claims. While the invention has been shown in only one of its forms, it should be apparent to those skilled in the art that it is not so limited but is susceptible to various changes without departing from the scope of the invention.

We claim:

1. A method of packaging a semiconductor solar cell that converts solar energy into electricity, the method comprising:
laminating an electrically insulative film to a metal substrate having a mounting paddle and two or more leads to thereby define a laminated structure, the metal substrate being positioned so that the mounting paddle separates from each of the two or more leads prior to being laminated to the electrically insulative film;
attaching a photovoltaic device to the mounting paddle of the laminated structure, wire bonding operatively connecting the photovoltaic device to the two or more leads; and
applying over material to affix the photovoltaic device to the mounting paddle of the laminated structure, the overmold material being applied such that a predetermined portion of the photovoltaic device is exposed to thereby allow the photovoltaic device to collect the solar energy.

2. A method as defined in claim 1, wherein the electrically insulative film is selected from a group consisting of at least one of a thermally conductive film and a flex circuitry type polyimide film.

3. A method as defined in claim 1, wherein the electrically insulative film includes a flex circuitry type polyimide film, the flex circuitry type polyimide film being plated with a metallic material to thereby enhance thermal properties of the flex circuitry type polyimide film.

4. A method as defined in claim 3, wherein the metallic material includes a copper alloy having one or more materials selected from a group consisting of nickel, manganese, cobalt, phosphorus, zirconium, silicon, silver, zinc, and iron.

5. A method as defined in claim 1:
wherein the laminated structure includes the electrically insulative film, the metal substrate bonded to a surface of the electrically insulative film, and a supporting copper sheet layer bonded to an opposite surface of the electrically insulative film, and wherein the electrically insulative film is a polyimide sheet layer and the metal substrate is a copper sheet layer; and
wherein the mounting paddle is separated from each of the two or more leads by etching away material from the copper sheet layer to thereby define the mounting paddle and the two or more leads.

6. A method as defined in claim 5, further comprising attaching a bypass diode to the mounting paddle of the metal substrate.

7. A method as defined in claim 5, further comprising etching away additional material from the copper sheet layer to form a copper-free border surrounding the mounting paddle and the two or more leads such that the polyimide sheet layer is exposed to thereby increase high potential values of the metal substrate.

8. A semiconductor solar cell package comprising:
a laminated structure having:
a leadframe including a mounting paddle and two or more leads and positioned so that the mounting paddle is separate from each of the two or more leads; and
an electrically insulative film abuttingly contacting a bottom portion of the leadframe;
a photovoltaic device recumbently supported by the mounting paddle of the laminated structure;
wire bonding operatively connecting the photovoltaic device to the two or more leads of the laminated structure;
overmold material positioned to affix the photovoltaic device to the mounting paddle of the laminated structure; and
an opening positioned in the overmold material such that a predetermined portion of the photovoltaic device is exposed to thereby allow the photovoltaic device to collect solar energy.

9. A semiconductor solar cell package as defined in claim 8, wherein the electrically insulative film is selected from a group consisting of a thermally conductive film and a flex circuitry type polyimide film.

10. semiconductor solar cell package as defined in claim 8, wherein the electrically insulative film includes a flex circuitry type polyimide film, the flex circuitry type polyimide film being plated with a metallic material.

11. A semiconductor solar cell package as defined in claim 10, wherein the metallic material includes a copper alloy having one or more materials selected from a group consisting of nickel, manganese, cobalt, phosphorus, zirconium, silver, and iron.

12. A machine for packaging a semiconductor solar cell that converts solar energy into electricity, the machine comprising:
a film device to convey an electrically insulative film under a lamination device;
the lamination device to laminate the electrically insulative film to a leadframe having a mounting paddle and two or more leads to thereby define a laminated structure, the leadframe being positioned so that the mounting paddle separates from each of the two or more leads;
a bonding component connected to the lamination device to attach a photovoltaic device to the mounting paddle of the laminated structure, the photovoltaic device having wire bonding that operably connects the photovoltaic device to the two or more leads; and
a top mold connected to the lamination device to apply overmold material that affixes the photovoltaic device to the mounting paddle, the overmold material being applied such that a predetermined portion of the photovoltaic device is exposed to thereby allow the photovoltaic device to collect the solar energy.

13. A machine as defined in claim 12, further comprising:
a removal device to remove the laminated structure from a bottom mold; and
a singulation device to singulate a semiconductor solar cell package comprising the photovoltaic device from the laminated structure.

14. A machine as defined in claim 12, further comprising:
a bottom mold positioned under the electrically insulative film when the lamination device laminates the electrically insulative film to the leadframe; and
a drawdown device to draw the electrically insulative film down into an inner surface of the bottom mold prior to positioning the leadframe on the electrically insulative film.

15. A machine as defined in claim 14, wherein the top mold compresses the electrically insulative film under the leadframe such that intrusion of the electrically insulative film is reduced when applying the overmold material.

16. A machine as defined in claim 12, wherein the electrically insulative film includes a flex circuitry type polyimide film, the flex circuitry type polyimide film being plated with a metallic material.

17. A machine as defined in claim 16, wherein the metallic material includes a copper alloy having one or more materials selected from a group consisting of nickel, manganese, cobalt, phosphorus, zirconium, silicon, silver, and iron.
